(19) United States
(12) Patent Application Publication
(10) Pub. No.: US 2006/0207872 A1
(43) Pub. Date: Sep. 21, 2006

(54) Dual magnetron thin film deposition system

(76) Inventor: Sergey Mishin, Goleta, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/085,362

(22) Filed: Mar. 21, 2005

(51) Int. Cl. C23C 14/32; C23C 14/00

(52) U.S. Cl. 204/192.1; 204/298.16

(57) ABSTRACT

A magnetron comprises a processing chamber having an upper sputtering target and a lower sputtering target positioned therein. The magnetron further comprises an upper magnetic structure positioned adjacent to the upper sputtering target and outside the processing chamber. The magnetron further comprises a lower magnetic structure positioned adjacent to the lower sputtering target and outside the processing chamber. The magnetron further comprises a rotatable magnet that is coupled to an exterior portion of the processing chamber. The rotatable magnet is configured to rotate around the processing chamber in a region adjacent to at least one of the upper and lower sputtering targets.

### FIELD OF THE INVENTION

The present invention relates generally to deposition of thin films by sputtering processes, and more specifically to the manipulation of a magnetic field within a processing chamber during thin film deposition by sputtering.

### BACKGROUND OF THE INVENTION

Physical vapor deposition by sputtering is a well known process that has widespread applications in the fabrication of integrated circuit semiconductor devices. In a conventional fabrication process, a large number of integrated circuit devices are formed on a thin, generally circular semiconductor substrate known as a wafer. Integrated circuit device fabrication commonly involves several processing steps. While sputtering has a wide variety of different applications in semiconductor processing, it is often used for reactive sputtering of dielectric films from conductive target materials. Such films include, but are not limited to, aluminum nitride and aluminum oxide.

A magnetron is a device that is used for depositing a film onto a wafer surface using a sputtering process. A conventional magnetron includes a processing chamber connected to a gas source and targets of sputterable material positioned within the chamber. In operation of the magnetron, a suitable DC or AC electric field is applied to the chamber, thereby causing a plasma of an inert gas in the chamber to be formed. A magnetic field is used to confine the plasma to a region near the sputterable target material. The target material is subjected to an electric potential and acts as a cathode with respect to an anode. This causes positive ions from the plasma to strike the targets which have a negative potential, thereby ejecting atoms from the targets. Ejected material from the targets is deposited as a thin film onto a wafer positioned in the chamber.

The sputterable target material is usually selected to yield a particular substance to be deposited on the wafer. For example, to deposit an aluminum nitride film onto a silicon wafer, an appropriate target material is aluminum. Aluminum nitride films are useful in the manufacture of piezoelectric acoustic resonator filters, including film bulk acoustic resonator (FBAR) filters.

### SUMMARY OF THE INVENTION

It is generally advantageous for thin films produced using a sputtering process to have relatively uniform physical and electrical properties across the film. Examples of such properties include, but are not limited to, thickness, stress characteristics and coupling coefficient. For example, in the manufacture of FBAR filters, the greater the uniformity in the film thickness, the higher the yield of the resulting filters. As another example, providing a film with a uniformly higher coupling coefficient generally yields a more efficient energy transfer between electrical and acoustic domains of an FBAR filter. That is, coupling coefficient is a measure of the piezoelectricity of the film, or of the ability of the film to convert acoustic energy to electrical energy and vice versa. Thin films with enhanced uniformity in physical or electrical properties also have applications in devices other than FBAR filters. An improved sputtering deposition system has been developed that provides greater control over certain properties of a deposited thin film.

In one embodiment of the present invention, a magnetron comprises a processing chamber having an upper sputtering target and a lower sputtering target positioned therein. The magnetron further comprises an upper magnetic structure positioned adjacent to the upper sputtering target and outside the processing chamber. The magnetron further comprises a lower magnetic structure positioned adjacent to the lower sputtering target and outside the processing chamber. The magnetron further comprises a rotatable magnet that is coupled to an exterior portion of the processing chamber. The rotatable magnet is configured to rotate around the processing chamber in a region adjacent to at least one of the upper and lower sputtering targets.

In another embodiment of the present invention, a magnetron comprises a processing chamber. The magnetron further comprises a first and second concentric targets for sputtering a film onto a wafer in the processing chamber in response to the generation of a plasma in the processing chamber. The magnetron further comprises a rotatable magnet that is configured to rotate around at least a portion of the processing chamber in a region adjacent to at least one of the first and second concentric targets.

In another embodiment of the present invention, a method comprises providing a processing chamber having a wafer and a sputtering target positioned therein. The method further comprises exposing the sputtering target to a first magnetic field. The method further comprises sputter depositing material from the sputtering target onto the wafer. The method further comprises exposing the sputtering target to a second magnetic field. The second magnetic field is time-varying during a period when the first magnetic field is substantially constant.

### BRIEF DESCRIPTION OF THE DRAWINGS

Exemplary embodiments of an improved thin film deposition system are illustrated in the accompanying drawings, which are for illustrative purposes only. The drawings comprise the following figures, in which like numerals indicate like parts.

FIG. 1A is a cross-sectional side view of an exemplary embodiment of a magnetron.

FIG. 1B is a top view of the sputtering targets and the magnetic structures provided in the magnetron of FIG. 1A.

FIG. 2A is a topographic map of a thin film grown on a wafer surface illustrating a thickness nonuniformity in the thin film due to an asymmetrical gas flow over the wafer surface.

FIG. 2B is a topographic map of a thin film grown on a wafer surface illustrating a thickness nonuniformity in the thin film due to an asymmetry in the upper target.

FIG. 2C is a topographic map of a thin film grown on a wafer surface illustrating a thickness nonuniformity in the thin film due to an asymmetry in the lower target.

FIG. 3 is a top view of the sputtering targets and magnetic structures that have been modified to provide more uniform film deposition on the wafer.

FIG. 4A is a cross-sectional side view of a modified embodiment of a magnetron including rotatable magnets.

FIG. 4B is a bottom view of the magnetron of FIG. 4A taken along line 4A-4A.

FIG. 5 is a cross-sectional side view of an exemplary embodiment of a magnetron having supplemental magnets placed above and below the magnetron.

### DETAILED DESCRIPTION OF PREFERRED EMBODIMENTS

As described herein, it is generally advantageous for thin films to have relatively uniform physical and electrical properties across the film. Several factors can cerate non-uniformities in thin films produced by sputtering. For example, the characteristics of the sputterable target material typically change throughout the life of the targets. Particularly, the cumulative effect of material erosion from a target gradually changes the shape of the surface of the target. This often changes the angle at which material is eroded from the target, which alters the rate of material deposition onto a wafer surface, thereby degrading the uniformity in thickness of films deposited as a target ages. Other sources of nonuniformities include asymmetrical gas flows in the processing chamber and interference from other nearby magnetrons. The challenge of providing uniform properties across a thin film has increased as wafer size as increased.

To increase uniformity of thin films deposited using a sputtering process, various modifications have been made to the conventional magnetron design. For example, the magnetic field in the processing chamber—which is generally spatially symmetrical—can be modified using a secondary magnetic field generated by either electromagnets or a fixed array of permanent magnets.

The secondary magnetic field is intended to compensate for nonuniformities caused by changes in the characteristics of the sputtering target, asymmetrical gas flows, surrounding magnetrons, and other factors. Specifically, the secondary magnetic field is used to manipulate the area from which the predominant amount of material is eroded from the sputtering targets. This area is commonly referred to as the “racetrack”. In a planar magnetron, the secondary magnetic field is used to adjust the position of the racetrack, thereby affecting film deposition around the perimeter of the wafer. In a conical magnetron, the secondary magnetic field is used to adjust the depth of the racetrack: a deeper racetrack has stronger self-shadowing, thereby causing less deposition from the deepened racetrack area of the target.

While these modified designs can nominally enhance the uniformity of the thin films deposited using a magnetron, they suffer from significant disadvantages. For example, the large size of electromagnets renders their use with many conventional magnetron configurations impractical. A fixed array of permanent magnets positioned around the perimeter of a magnetron can be used to adjust deposition thickness only around the perimeter of the wafer. Furthermore, the nature of these conventional adjustments typically limits the usefulness of the magnetic improvement to only about 5% to about 10% of the life of the sputtering target. Additionally, secondary magnetic fields generated by electromagnets or a fixed array of permanent magnets are not capable of correcting nonuniformities resulting from nonuniform grain structure in the sputtering target. Specifically, each target is unique on a molecular level, and therefore will need a different degree of compensation from the secondary magnetic field. Conventional electromagnets and fixed arrays of permanent magnets are not readily capable of adjusting for these variances, which tend to be more pronounced in conical magnetrons.

In accordance with the foregoing, an improved system for adjusting the magnetic field in a magnetron system has been developed. This improved system allows thin films with greater uniformity in both physical and electrical characteristics to be deposited, as compared with films deposited using conventional systems. An exemplary embodiment of this improved system includes two distinct mechanisms for controlling the magnetic field inside the magnetron processing chamber, thereby compensating for nonuniformities caused by both systematic issues (such as nonuniform gas flows in the process chamber) and random issues (such as erosion or varying grain patterns in sputtering targets).

One mechanism allows the magnetic field to be fine tuned to provide a desired asymmetry in the processing chamber magnetic field. This asymmetry can be used to compensate for systematic nonuniformities resulting from effects such as uneven gas flows or other system components that affect film deposition is a consistent manner.

Another mechanism allows for compensation due to nonuniformities caused by more random sources, such as erosion or varying grain patterns in the sputtering targets. In an exemplary embodiment, a secondary set of movable magnets are positioned around the exterior of the processing chamber. These movable magnets are positioned on nonmagnetic rings that are driven by a computer-controlled motor. The magnets can be positioned around the perimeter of the wafer and/or above and below the wafer. This arrangement provides compensation for nonuniformities resulting from more random effects such as erosion or varying grain patterns in sputtering targets. This arrangement also provides compensation for nonuniformities that manifest themselves across the wafer, rather than only at the wafer perimeter.

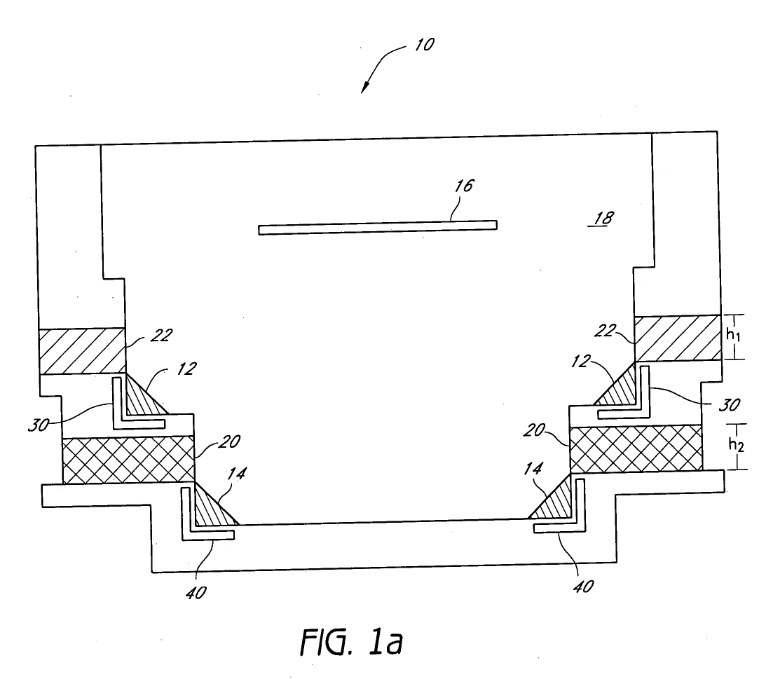

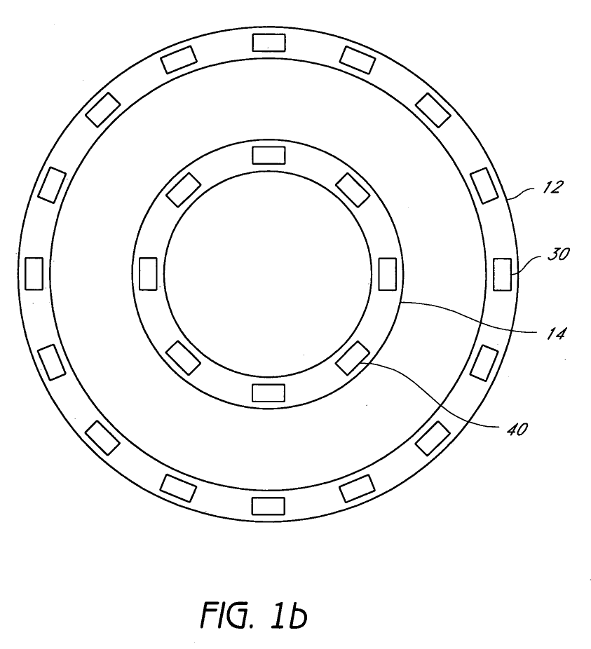

A cross-sectional side view of an exemplary embodiment of a magnetron is illustrated in FIG. 1A. The magnetron 10 includes an upper target 12 and a lower target 14. In this example, the targets have conical shapes, although other shapes—such as rings, circles and ellipses—are used in other embodiments. A top view of the targets 12, 14 is provided in FIG. 1B

Still referring to FIG. 1A, the exemplary magnetron further includes an upper magnetic structure 30 and a lower magnetic structure 40. The magnetic structures 30, 40 are configured to generate magnetic fields that act on the targets 12, 14. The magnetic structures 30, 40 are located behind horizontal and vertical edges of the targets 12, 14, respectively. The magnetron 10 includes a chamber 18 that encloses a wafer 16 on which a thin film is to be formed. The wafer is supported by a wafer supporting assembly.

As described herein, during a sputtering operation a gas is supplied into the chamber 18 and electrical potentials are applied to the targets 12, 14. A plasma of the gas is formed in the chamber, which causes ions to accelerate towards and impact the targets 12, 14. This causes erosion of material from the targets 12, 14; this material is subsequently deposited onto the wafer 16.

The chemical composition of the gas in the chamber 18, together with the material comprising the targets 12, 14, are preselected for deposition of a desired substance onto the wafer 16. In one embodiment, magnetron 10 is used for sputtering thin films of highly piezoelectric aluminum nitride. In such an embodiment, the chamber contains a mixture of nitrogen and argon gas, the targets 12, 14 comprise aluminum, and the wafer 16 is a silicon wafer.

In one embodiment, the electrical potentials applied to the targets 12, 14 are reversed in polarity at a frequency of about 40 kHz. Periodic reversal of the electrical potentials causes ions to alternate between striking upper target 12 and lower target 14, thereby promoting erosion from both targets in a relatively even pattern.

As illustrated in FIGS. 1A and 1B, the targets 12, 14 are conical, having a center axis aligned collinearly with a center axis of the opposing wafer 16. Upper magnetic structure 30 produces a magnetic field associated with upper target 12, and lower magnetic structure 40 produces a magnetic field associated with lower target 14. The strength and position of the magnetic field generated by the magnetic structures 30, 40 are adjustable, thereby enabling control over properties such as film thickness, film stress characteristics. In certain embodiments, manipulating the magnetic field also allows a highly piezoelectric film structure to optionally be produced.

For example, in one embodiment, the upper magnetic structure 30 includes between 12 and 60 horizontal magnets, between 20 and 60 vertical magnets, between 20 and 180 individual pole pieces and two common pole pieces. Other numbers of magnets and pole pieces are used in other embodiments. The film deposition pattern is adjustable by changing the size and strength of the magnets, and the shape of the pole pieces, in the upper magnetic structure 30. For example, manipulating the magnets and pole pieces that comprise the upper magnetic structure 30 allows the racetrack in the upper target 12 to be manipulated. Changing the racetrack position on the upper target 12 affects the angle, energy, and amount of sputtered material deposited on the surface of the wafer 16 from the upper target 12.

Additionally, the deposition rate and the piezoelectric properties of the film deposited onto the wafer 16 are controllable based on the strength of the magnetic filed generated by the upper magnetic structure 30. A low magnetic field strength from the upper magnetic structure 30 yields a higher deposition rate. A magnetic field strength that acts on the upper target 12 that is too low or too high reduces the coupling coefficient of the film deposited on the wafer 16. Therefore, magnetic field strength affects both film thickness and coupling coefficient.

As another example, in one embodiment the lower magnetic structure 40 includes between 14 and 42 horizontal magnets and between 14 and 42 vertical magnets. The lower magnetic structure also includes between 14 and 126 individual pole pieces and two common pole pieces. Other numbers of magnets and pole pieces are used in other embodiments. The film deposition pattern is adjustable by changing the size and strength of the magnets, and the shape of the pole pieces, in the lower magnetic structure 40. Specifically, manipulating the magnets and pole pieces that comprise the lower magnetic structure 40 allows the racetrack in the lower target 14 to be manipulated. Changing the racetrack position on the lower target 14 affects the angle, energy and amount of sputtered material deposited on the surface of the wafer 16 from the lower target 14.

Additionally, the deposition rate and the piezoelectric properties of the film deposited onto the wafer 16 are controllable based on the strength of the magnetic filed generated by the lower magnetic structure 40. A low magnetic field strength from the lower magnetic structure 40 yields a higher deposition rate. A magnetic field strength that acts on the lower target 14 that is low or high reduces the coupling coefficient of the film deposited on the wafer 16. Therefore, magnetic field strength affects both film thickness and coupling coefficient.

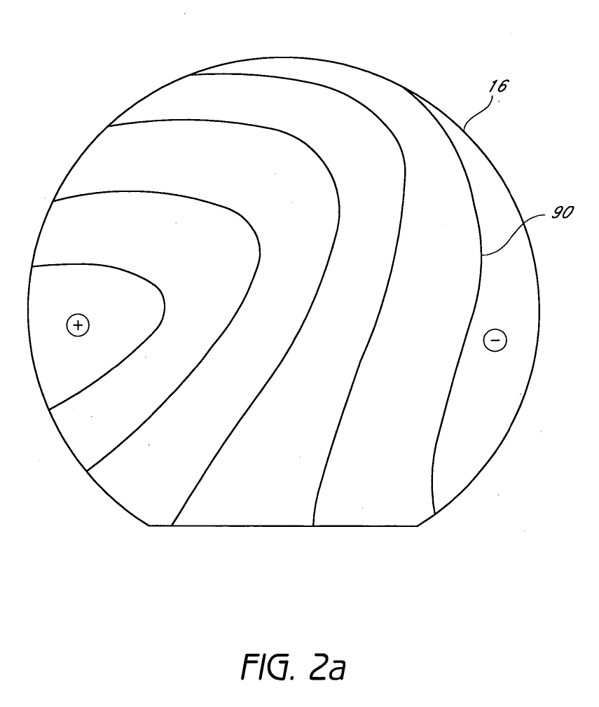

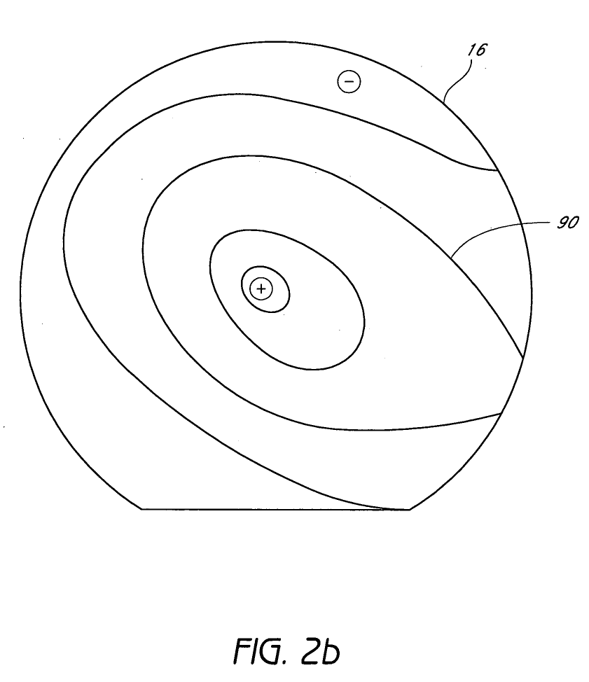

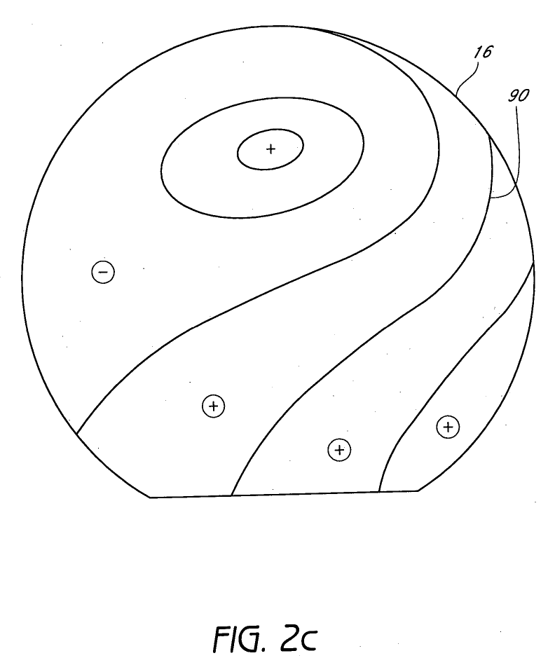

FIG. 2A is an example topographical map of the thickness of a thin film deposited on wafer 16. Topographical lines 90 illustrate lines of constant film thickness on the wafer surface. Therefore, a wafer having a perfectly uniform film deposited thereon would have no topographical lines. Likewise, the presence of topographical lines 90 indicate a film of non-uniform thickness. Information about the source of the nonuniformity can be discerned from the pattern of the topographical lines 90. For example, the pattern of topographical lines 90 illustrated in FIG. 2A suggests the presence of a nonuniform gas flow over the surface of the wafer, which could be caused by, for example, the magnetron pumping system or asymmetries in the process chamber 18. Likewise, the pattern of topographical lines 90 illustrated in FIG. 2B suggests the presence of an asymmetry in the upper target 12. The pattern of topographical lines 90 illustrated in FIG. 2C suggests the presence of an asymmetry in the lower target 14. As described above, asymmetries in the targets 12, 14 often develop over time as sputtered material erodes from the targets.

In one embodiment, the magnetic structures 30, 40 are adjusted to compensate for nonuniform film deposition, such as that illustrated in FIGS. 2A through 2C. For example, adjusting the size of the magnets and/or the pole pieces that comprise the magnetic structures 30, 40 promotes a custom target erosion pattern. The target erosion pattern is configurable to compensate for effects such as nonuniformities in the chamber gas flow and in the target erosion patterns.

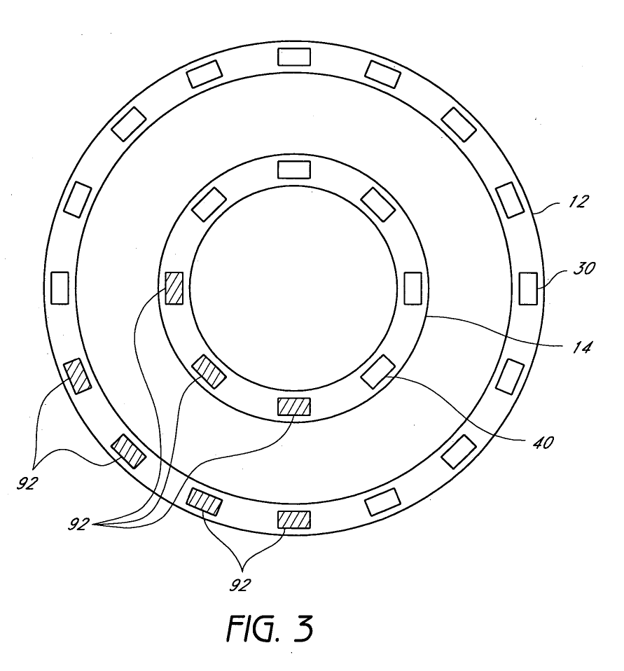

To compensate for a nonuniform film growth pattern, such as the growth pattern illustrated in FIG. 2A, stronger magnets are positioned adjacent to selected regions of the targets 12, 14. For example, in one particular embodiment, stronger magnets 92 are positioned at three locations adjacent to the lower target 14 and at four locations adjacent to the upper target 12. This modified arrangement is illustrated in FIG. 3. For example, in one embodiment the stronger magnets 92 are approximately 10% stronger than the other magnets comprising the magnetic structures 30, 40. In other embodiments, the stronger magnets 92 are approximately 5%, approximately 15%, or approximately 20% stronger than the other magnets. Other strength differentials are used in other embodiments. Generally, increasing the magnetic field in a selected region of the wafer 16 will reduce the deposition rate in that region.

In an exemplary embodiment, the magnetic field is fine tuned by making small adjustments to the position and orientation of the magnetic structures 30, 40, including the stronger magnets 92. Advantageously, once the position and orientation of the magnetic structures 30, 40 have been adjusted to compensate for systematic nonuniformities of a particular magnetron 10, such as those owing to nonuniform gas flows or asymmetries in the process chamber, the need for further adjustment over the life of the magnetron may be greatly reduced.

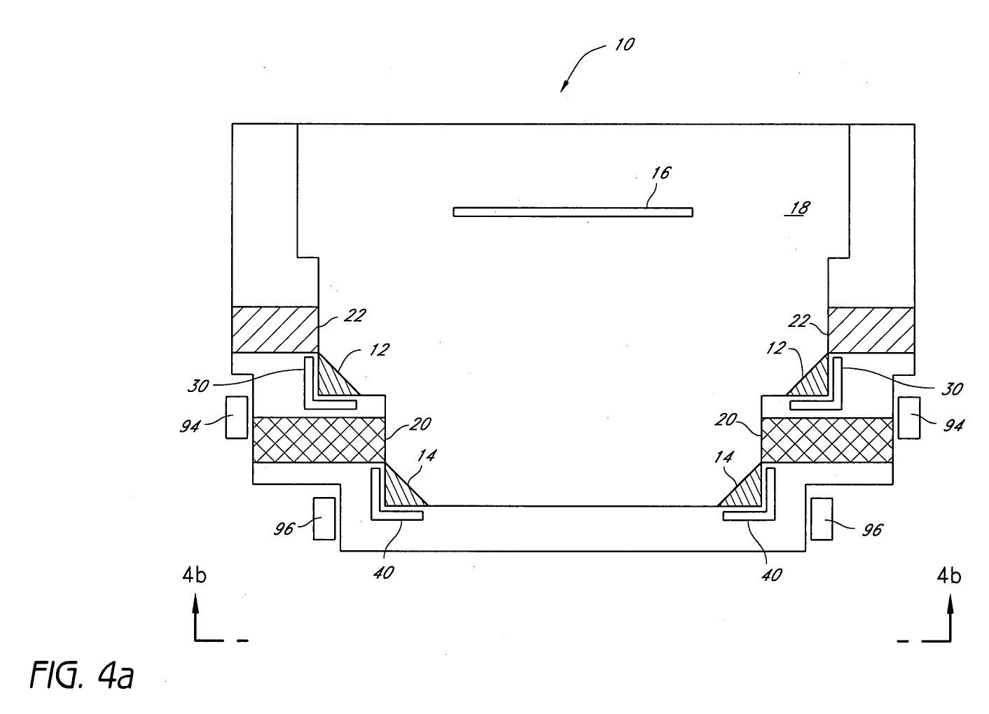

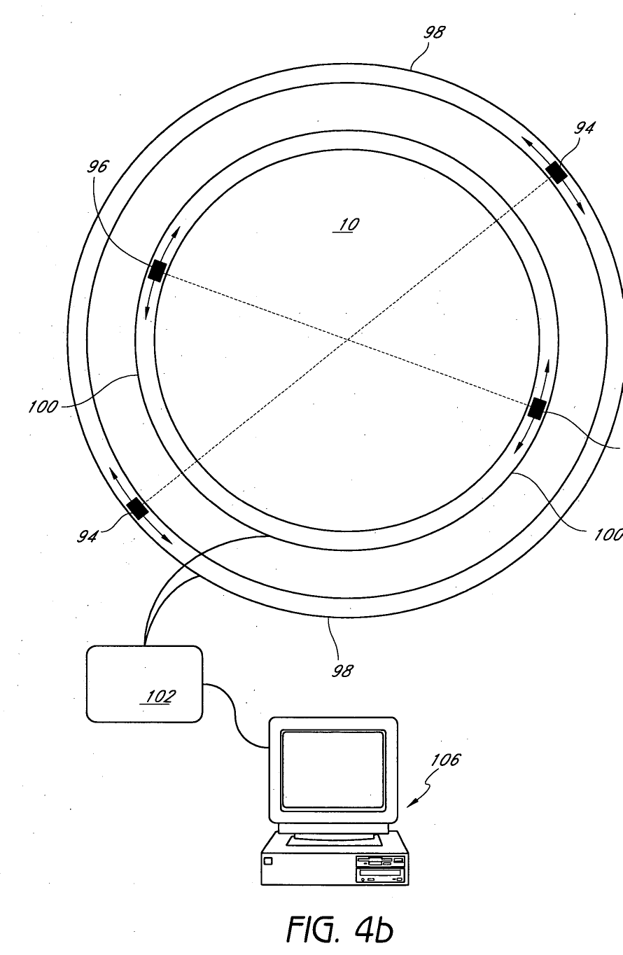

Additionally or alternately, one or more rotatable magnets are positioned around a circumference of the magnetron 10, as illustrated in FIGS. 4A and 4B. Specifically, FIG. 4A illustrates an upper pair of rotatable magnets 94 and a lower pair of rotatable magnets 96 positioned around a circumference of the magnetron 10 in a region adjacent to the upper target 12 and lower target 14, respectively. As shown in the exemplary embodiment illustrated in FIG. 4B, the upper and lower pairs of rotatable magnets 94, 96 are mounted on upper and lower circular tracks 98, 100, respectively. In such embodiments, the rotatable magnets 94, 96 are movable around the circular track 98, 100, as indicated by the arrows in FIG. 4B. The pole orientation of one or more of the rotatable magnets 94, 96 is adjustable.

In one embodiment, a computer-controlled motor 102 is used to control movement of the rotatable magnets 94, 96 along the circular tracks 98, 100. For example, in one embodiment, the motor 102 is configured to control movement of a group of rotatable magnets, while in other embodiments the motor 102 is configured to control movement of one or more rotatable magnets individually. In the exemplary embodiment illustrated in FIG. 4B, computer 106 is programmed to control movement of the rotatable magnets 94, 96.

In a modified embodiment, film thickness is monitored and/or measured during deposition. One or more of these measurements are then used to adjust movement of the rotatable magnets 94, 96 in a way that enhances film uniformity, thereby providing a real time feedback system. In other embodiments, other properties of the deposited film—such as film thickness, stress characteristics, and coupling coefficient—are measured after deposition. One or more of these measurements are then used to adjust movement of the rotatable magnets 94, 96 in a way that enhances film uniformity during a subsequent deposition process.

Although the rotatable magnets 94, 96 illustrated in FIGS. 4A and 4B are provided in pairs, in a modified embodiment one rotatable magnet is provided on each circular track 98, 100. In still other embodiments, more than two rotatable magnets are provided on each circular track 98, 100, such as three rotatable magnets or four rotatable magnets. In still other embodiments, the rotatable magnets are not evenly spaced on the circular track. In still other embodiments, the quantity of rotatable magnets provided on the upper circular track 98 is different than the quantity of rotatable magnets provided on the lower circular track 100.

In an exemplary embodiment, the rotatable magnets 94, 96 are capable of compensating for nonuniformities in the thickness of the thin film deposited on the wafer. For example, the rotatable magnets 94, 96 are used to (a) increase the magnetic field in a region of the wafer where the film growth rate is to be reduced, and/or (b) decrease the magnetic field in a region of the wafer where the film growth rate is to be increased. Whether the rotatable magnets 94, 96 increase or decrease the magnitude of the magnetic field in a particular region of the wafer depends on how the field produced by the rotating magnets interacts with the field produced by the magnetic structures 30, 40.

In one embodiment, the rotatable magnets 94, 96 are rotated around the processing chamber 18 with a variable angular velocity. This causes the rotatable magnets 94, 96 to have an increased effect in the region of the wafer 16 adjacent where the angular velocity is low, and to have a decreased effect in the region of the wafer 16 adjacent where the angular velocity is high. In a modified embodiment, the rotatable magnets 94, 96 are not rotated around the processing chamber, but rather are oscillated adjacent a region of the wafer 16 where they are to have an increased effect.

The size of the region of the wafer 16 where the rotatable magnets 94, 96 are to have an increase effect is at least partially dependent on the characteristics of the film thickness nonuniformity. For example, in one embodiment the rotatable magnets are configured to have a decreased angular velocity, or are configured to oscillate in a region comprising approximately 120° of the wafer circumference.

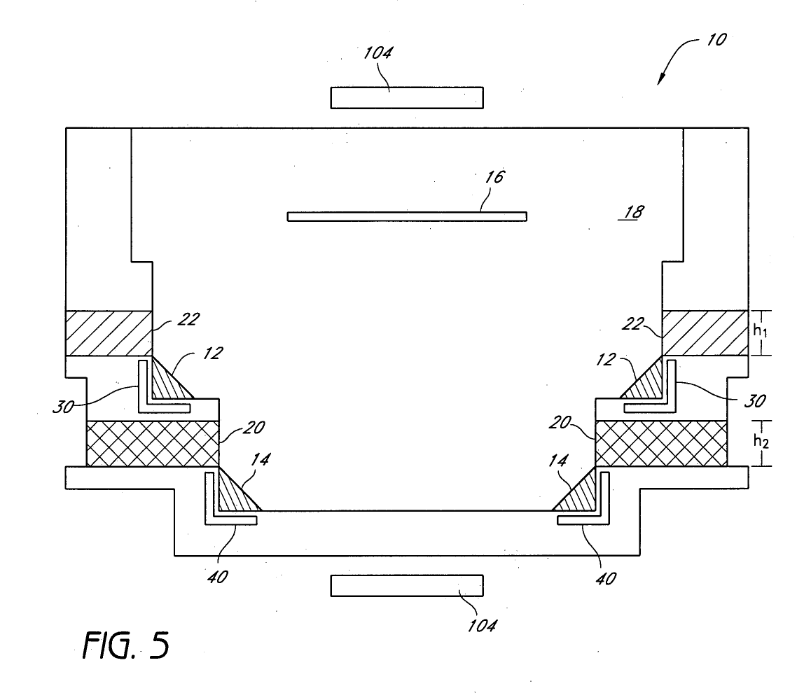

Another technique for reducing or eliminating nonuniformities in a sputter-deposited thin film is to position supplemental magnets above and/or below the wafer. Optionally, supplemental magnets are positioned above and/or below the wafer in addition to movable magnets placed around the circumference of the wafer, as illustrated in FIGS. 4A and 4B. FIG. 5 illustrates an exemplary embodiment of a magnetron 10 having supplemental magnets 104 placed above and below the wafer 16.

The rotatable magnets 94, 96 are particularly useful for compensating for nonuniformities present around the circumference of the wafer 16, the supplemental magnets 104 illustrated in FIG. 5 are particularly useful for compensating for nonuniformities present in the center of the wafer 16. The size of the supplemental magnets 104 at least partially determines the area of the wafer 16 over which sputter deposition is affected. Specifically, decreasing the size of the supplemental magnets 104 causes a greater impact in deposition rate at the center of the wafer 16, whereas increasing the size of the supplemental magnets 104 causes a greater impact is deposition rate around the edge of the wafer 16. As with the rotatable magnets 94, 96, the shape and orientation of the supplemental magnets 104 is configurable to enhance or reduce the magnetic field produced by the magnetic structures 30, 40. Furthermore, in modified embodiments supplemental magnets are positioned only above or only below the processing chamber 18.

The mechanisms described herein for manipulating the magnetic field in a magnetron processing chamber 18 allow thin films with fewer non-uniformities to be formed. The nonuniformities can be in the electrical characteristics of the film, such as film coupling coefficient, or can be in the physical characteristics of the film, such as film thickness. For example, the mechanisms described herein allow thin films with enhanced thickness uniformity to be manufactured, which is particularly advantageous in the manufacture of FBAR filters.

An FBAR filter is a series of electrically connected, air suspended membrane-type resonators of a piezoelectric material, such as aluminum nitride or zinc oxide, sandwiched between metallic electrodes, such aluminum or molybdenum. The resonant frequency of an FBAR filter is at least partially dependent on the thickness of the piezoelectric material. FBAR filters are formed on silicon wafers using sputter deposition techniques and apparatuses disclosed herein. In one embodiment, a 150 mm silicon wafer holds over 10⁴ individual filters. Using the techniques disclosed herein, the filters on a silicon wafer have a resonant frequency that is within 0.2% of a nominal center frequency. To accomplish this, the 1σ thickness uniformity of an aluminum nitride layer deposited over the wafer surface is 0.2%, which produces a filter yield of 70%. In contrast, if the 1σ thickness uniformity falls to 1%, a yield of only 14% will result, rendering commercial fabrication problematic.

### SCOPE OF THE INVENTION

While the foregoing detailed description discloses several embodiments of the present invention, it should be understood that this disclosure is illustrative only and is not limiting of the present invention. It should be appreciated that the specific configurations and operations disclosed can differ from those described above, and that the methods described herein can be used in contexts other than deposition of thin films.

We claim:

1. A magnetron comprising:
a processing chamber having an upper sputtering target and a lower sputtering target positioned therein;
an upper magnetic structure positioned adjacent to the upper sputtering target and outside the processing chamber;
a lower magnetic structure positioned adjacent to the lower sputtering target and outside the processing chamber; and
a rotatable magnet that is coupled to an exterior portion of the processing chamber, and that is configured to rotate around the processing chamber in a region adjacent to at least one of the upper and lower sputtering targets.

2. The magnetron of claim 1, further comprising a computer-controlled motor configured to controllably move the rotatable magnet around at least a portion of the processing chamber.

3. The magnetron of claim 1, wherein a first rotatable magnet is configured to rotate around the upper sputtering target and a second rotatable magnet is configured to rotate around the lower sputtering target.

4. The magnetron of claim 1, further comprising a supplemental magnet positioned on a processing chamber center axis, wherein the upper and lower magnetic structures and the upper and lower sputtering targets are positioned around the processing chamber center axis.

5. The magnetron of claim 1, further comprising:
a wafer positioned within the processing chamber on a processing chamber center axis; and
a supplemental magnet positioned on the processing chamber center axis, wherein the upper and lower magnetic structure and the upper and lower sputtering targets are positioned around the processing chamber center axis.

6. A magnetron comprising:
a processing chamber;
a first and second concentric targets for sputtering a film onto a wafer in the processing chamber in response to the generation of a plasma in the processing chamber; and
a rotatable magnet that is configured to rotate around at least a portion of the processing chamber in a region adjacent to at least one of the first and second concentric targets.

7. The magnetron of claim 6, further comprising a computer-controlled motor configured to controllably move the rotatable magnet around at least a portion of the processing chamber.

8. The magnetron of claim 6, further comprising:
a motor configured to controllably move the rotatable magnet around at least a portion of the processing chamber; and
a computer configured to control the motor based on one or more film property measurements taken during deposition of the film onto the wafer.

9. The magnetron of claim 6, further comprising a supplemental magnet positioned on a processing chamber center axis, wherein the pair of concentric targets are positioned around the processing chamber center axis.

10. A method comprising:
providing a processing chamber having a wafer and a sputtering target positioned therein;
exposing the sputtering target to a first magnetic field;
sputter depositing material from the sputtering target onto the wafer; and
exposing the sputtering target to a second magnetic field, wherein the second magnetic field is time-varying during a period when the first magnetic field is substantially constant.

11. The method of claim 10, further comprising exposing the sputtering target to a third magnetic field, wherein the third magnetic field is substantially constant while the second magnetic field is time-varying, and wherein the third magnetic field is orthogonal to the first magnetic field.

12. The method of claim 10, further comprising exposing the sputtering target to a third magnetic field, wherein the third magnetic field is generated using a magnet positioned adjacent an upper surface of the wafer.

13. The method of claim 10, wherein the sputter deposition occurs while the second magnetic field is being varied.

14. The method of claim 10, wherein the second magnetic field is applied from a magnet that is moved along an external portion of the processing chamber.

15. The method of claim 10, wherein the second magnetic field is applied from a magnet that is rotated around the processing chamber.

16. The method of claim 10, wherein the second magnetic field is applied from a magnet that is rotated around the processing chamber with a time-varying angular velocity.

17. The method of claim 10, further comprising rotating a magnet around an external portion of the processing chamber to generate the second magnetic field.
